(19) United States
(12) Patent Application Publication
(10) Pub. No.: US 2009/0238308 A1
(43) Pub. Date: Sep. 24, 2009

(54) Ultra low-power transmission system

(75) Inventors: Douglas B. Weiner, Plano, TX (US); Richard C. Eden, Briarcliff, TX (US)

Correspondence Address: DOCKET CLERK, P.O. DRAWER 800889, DALLAS, TX, 75380, US

(73) Assignee: Crane Co., Stamford, CT (US)

(21) Appl. No.: 12/077,601

(22) Filed: Mar. 19, 2008

(51) Int. Cl. H03D 3/00; H04L 27/14

(52) U.S. Cl. 375/334

(57) ABSTRACT

An ultra low-power transmission system for use with a battery-operated device. The ultra-low power transmission system comprises an encoded transmitter and an addressable ultra -low power receiver. The ultra low-power receiver comprises an RF front-end block for receiving and demodulating an incoming RF signal. The RF front-end block includes an amplifier for amplifying the received RF signal and a frequency discriminator for demodulating the amplified RF signal to produce a baseband signal. The amplifier and the frequency discriminator are each comprised of enhancement mode, high-mobility electron transistors (E-HEMTs). The ultra low-power further receiver comprises a correlator for receiving the baseband signal from the frequency discriminator and detecting a codeword therein. The correlator comprises a plurality of switched capacitors for storing samples of the baseband signal. The correlator is operable to couple the plurality of switched capacitors in order to integrate the samples stored thereon.

### TECHNICAL FIELD OF THE INVENTION

The present application relates generally to wireless systems and, more specifically, to an ultra low-power receiver for use in a battery-powered system with long operational life.

### BACKGROUND OF THE INVENTION

Battery-powered wireless devices are used in a wide variety of applications. These applications include common commercial devices, such as cell phones, PDAs, hand-held GPS location devices, and the like. These applications also include more exotic applications, such as military reconnaissance or surveillance devices (e.g., microsensors) and equipment or personnel tagging (tracking) devices.

A fundamental design objective in all of these applications is maximizing the battery lifespan by reducing power consumption. Many power management techniques are known in the prior art for reducing power consumption to thereby extend the operating lifespan of the battery. However, all of the conventional power management techniques suffer some type of drawback.

One common power management technique is duty cycling, wherein a wireless device goes into a low-power dormant state for an extended period of time (anywhere from, for example, seconds to hours) and then wakes up into a high-power awake state to check for incoming messages or to transmit an outgoing message, before returning to the low-power dormant state. However, during the dormant state, the deactivated receiver portion of the wireless device cannot receive an incoming message. As a result, the incoming message must be held or repeatedly transmitted until the next awake state, at which time the powered-up receiver portion can receive and demodulate the incoming message and the wireless device can take action. Thus, duty cycling results in increased latency in the operation of the wireless device.

Many wireless devices use passive RFID devices as a means to reduce power consumption. The passive RFID device draws its power from the energy of the signal transmitted by the reader device. However, while this gives the RFID device an extremely long lifespan, the reader device must be relatively close to the RFID device in order for it to operate. This severely limits the operating range of an RFID device.

Therefore, there is a need in the art for an improved battery-powered wireless device that has a long battery lifespan and an always-on capability that reduces latency. There is a further need for such a battery-powered wireless device to have high sensitivity for long range capability.

### SUMMARY OF THE INVENTION

To address the above-discussed deficiencies of the prior art, it is a primary object to provide, a transmission system with individually addressable receivers in which the receivers are battery-operated devices with an ultra low energy consumption, or ultra low-power receivers which are highly sensitive (able to detect a very low radiated RF power level). According to an advantageous embodiment, the ultra low-power receiver comprises: 1) a radio frequency (RF) front-end block for receiving and demodulating an incoming RF signal. The RF front-end block includes: i) an amplifier for amplifying the received RF signal, the amplifier comprising a first plurality of low-power RF transistors such as enhancement-mode high-mobility electron transistors (E-HEMTs); and ii) a frequency discriminator for demodulating the amplified RF signal to thereby produce a baseband signal, the frequency discriminator comprising a second plurality of low-power RF transistors. The ultra low-power receiver further comprises: 2) a correlator for receiving the baseband signal from the frequency discriminator and detecting a codeword therein.

In an advantageous embodiment of the present invention, the ultra low-power receiver may comprise one or more low-voltage, high-efficiency power converters that provide low VDD supply voltage(s) needed for the RF front-end and optionally, for the correlator and other functions (e.g., clock and control logic).

In one embodiment of the present invention, the correlator comprises a plurality of switched capacitors for storing samples of the baseband signal.

In another embodiment of the present invention, the correlator is operable to couple the plurality of switched capacitors in order to integrate the samples stored thereon.

In a further embodiment of the present invention, the RF front-end block operates from a first DC power supply of less than approximately 0.2 volts.

In a still further embodiment of the present invention, the correlator operates from a second DC power supply of between approximately 0.5 volts and 1.8 volts.

It is another primary object of the present invention to provide a wireless communication system comprising: 1) a transmitter for transmitting to a plurality of ultra low-power receivers a modulated downlink signal having a constant power envelope and relatively narrow spectrum; and 2) the plurality of ultra low-power receivers for receiving the modulated downlink signal. Each of the ultra low-power receivers comprises a radio frequency (RF) front-end block for receiving and demodulating the modulated downlink signal, wherein the RF front-end block includes: i) an amplifier for amplifying the received modulated downlink signal, the amplifier comprising a first plurality of enhancement mode, high-mobility electron transistors; and ii) a frequency discriminator for demodulating the amplified modulated downlink signal to thereby produce a baseband signal, the frequency discriminator comprising a second plurality of enhancement mode, high-mobility electron transistors. Each of the ultra low-power receivers further comprises a correlator for receiving the baseband signal from the frequency discriminator and detecting a codeword therein.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates a communication system in which an ultra low power receiver according to the principles of the present disclosure may operate;

FIG. 2 is a high level block illustrating an ultra low power receiver according to one embodiment of the disclosure;

FIG. 3 illustrates in greater detail the RF front-end of an ultra low power receiver according to one embodiment of the present disclosure; and

FIG. 4 illustrates in greater detail the frequency discriminator of an ultra low power receiver according to one embodiment of the present disclosure.

### DETAILED DESCRIPTION OF THE INVENTION

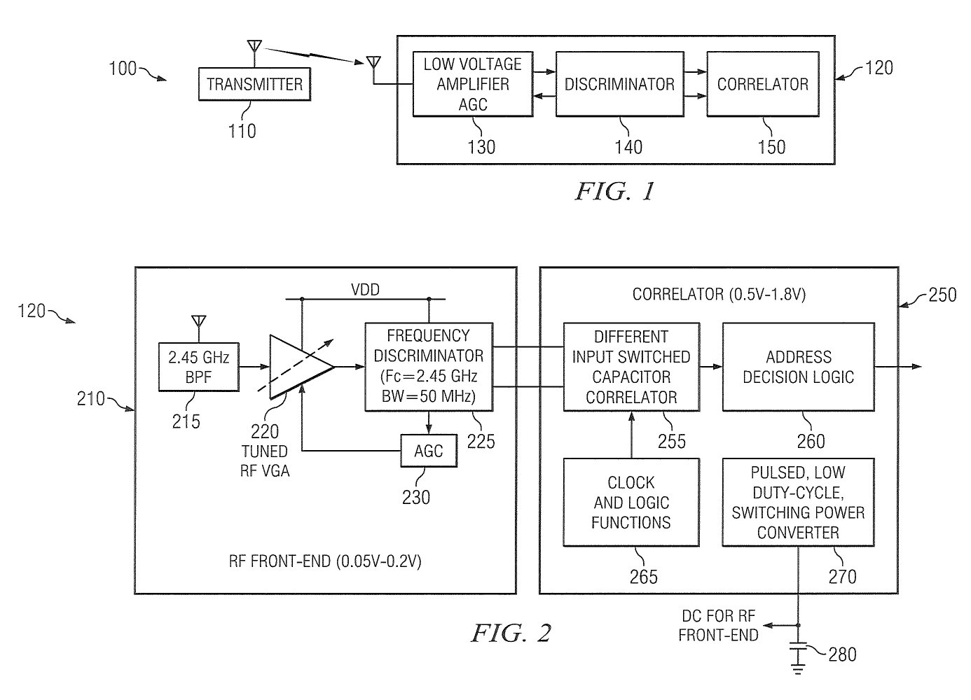

FIGS. 1 through 4, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged wireless receiver.

The present disclosure is directed to a wireless receiver that exhibits a long operational life, high-sensitivity reception, low response latency, and tolerance to interference. The ultra low-power receiver exhibits long operational life, since it may be left on continuously on for a period of years using only a small coin-cell or AA battery. The ultra low-power receiver is highly sensitive because an active (not passive) radio frequency (RF) front-end is used, including a low-noise amplifier (LNA) that provides the receiver with good noise figure. The ultra low-power receiver exhibits low latency since it is run in a continuously ON fashion. No delay is needed while waiting for the receiver to turn itself on. Also, the ultra low-power receiver comprises a low-power correlator designed to detect specific modulation signatures. This allows each receiver to be individually addressable, thus allowing the user to wake up only the receiver(s) in which he is interested.

The ultra low-power receiver exhibits long operational life due to its extremely low power draw. In one embodiment of the disclosure, a total power draw of 100 μWatts (μJ/s) is projected. At 3 volts nominal, every AH is equivalent to 3*3600 J (or 10,800,000,000 μJ). Hence, a 3 volt cell with 1 mAH of capacity can power the exemplary receiver for 10,800,000,000 μJ/(100 μJ/s)=108,000,000 seconds (i.e., 30,000 hours or 3.425 years). Typical coin-cell capacity can be as large as 600 mAH (0.6 AH) which would last 2.055 years. AA batteries are available in 2400 mAH (2.4 AH) values, which would last 2.4*30,000=72,000 hours (i.e., 8.22 years).

An ultra low power receiver according to the present disclosure has high sensitivity because the radio frequency (RF) front-end is completely active. The front end amplifiers are biased within the active region. A good noise figure results, which translates into a high sensitivity receiver. A sensitivity of −90 dBm may be achieved, a factor of 100 improvement over the best reported system of similar capability.

Because the ultra low power receiver is capable of being operated in a continuously-ON manner, it is possible to achieve a latency that is only associated with the propagation of the signal through the semiconductors and correlator function of the receiver. This is a great improvement over receiver systems that achieve low power consumption using duty cycling. Duty cycling receivers incur latency associated with the OFF time of the receiver and possible additional latency associated with synchronization of the transmitter and receiver schedule.

FIG. 1 illustrates communication system 100, in which an ultra low power receiver according to the principles of the present disclosure may operate. Communication system 100 comprises transmitter 110 and ultra low power receiver 120. Transmitter 110 may be, for example, the transmitter portion of the transceiver in, for example, a base station of a cellular or WiMAX network. Also, ultra low power receiver 120 may be only the receiver portion of a transceiver in a larger system that operates from a battery, such as, for example, a tracking device (e.g., equipment tag) or a remote sensor (e.g., surveillance system). For the purposes of simplicity and clarity in explaining the operation of the present invention, the remaining portions of transmitter 110 and ultra low power receiver 120 are omitted.

Ultra low power receiver 120 comprises ultra-low power, low supply voltage, radio frequency (RF) amplifier 130, frequency discriminator 140, and correlator 150. A feedback loop, for example, from discriminator 140, provides automatic gain control (AGC) to RF amplifier 130. The output of discriminator 140 is coupled to the input of correlator 150.

To achieve ultra low power operation and tolerance to interference, communication system 100 uses a downlink signal (or downlink waveform) that can be easily demodulated and quickly correlated with minimum power consumption. Thus, the encoded transmission in the downlink from transmitter 110 to ultra low power receiver 120 uses a robust modulation scheme in which the modulated waveform has a constant envelope and a narrow power spectrum. In a preferred embodiment of system 100, a frequency shift keying (FSK) modulation technique is encoded in transmitter 110 using orthogonal codes (e.g., Walsh codes) or near orthogonal codes that have good auto-correlation and cross-correlation characteristics. The power of transmitter 110 is variable depending upon the desired operational range of communication system 100 and the interference level of the operational environment.

Non-coherent detection is employed by receiver 120 to reduce the hardware complexity and thus power consumption. The use of non-coherent detection also means receiver 120 is suitable for use with a frequency agile transmitter. A direct conversion receiver (homodyne) is used to further address the key requirement of low power draw. A direct-conversion architecture receiver translates the received signal from RF directly to baseband eliminating the need for local oscillators, mixers, image-reject filters and other power consuming IF components.

Correlator 150 uses a passive sampling approach implemented with switched capacitors (powered principally from the signal inputs from the discriminator, so that it needs only a very small amount of DC power) to direct the signal combining and summing and differencing actions used to implement the correlator function. One advantageous aspect of correlator 150 is that the analog signal voltage samples are not moved after the samples are initially acquired, but rather remain stationary as charges on capacitors, until the sample are actually used in the correlation calculations. This provides an enormous savings in power.

FIG. 2 is a high level block illustrating ultra low power receiver 120 according to one embodiment of the disclosure. Receiver 120 comprises radio frequency (RF) front-end block 210, which operates from a power supply voltage in the range of 0.05-0.2 volts, correlator block 250, which operates from a power supply voltage in the range of 0.5-1.8 volts, and capacitor 280, which in one preferred embodiment may be implemented with a “super-capacitor”. Correlator block 250 corresponds to correlator 150 in FIG. 1. RF front-end block 210 further comprises band pass filter (BPF) 215, tuned RF variable gain amplifier (VGA) 220, relatively wideband (e.g., 50 MHz) frequency discriminator 225, and automatic gain control (AGC) block 230. Frequency discriminator 225 corresponds to discriminator 140 in FIG. 1.

Correlator block 250 further comprises differential input switched capacitor correlator 255, address decision logic 260, clock and logic functions block 265, and pulsed, low duty-cycle switching power converter 270. According to the principles of the present invention, RF front-end block 210 is implemented using ultra low-power RF transistors capable of providing RF gain at extremely low supply voltages and current levels. Such RF transistors typically have very short FET channel lengths (e.g., 35 nm). In an advantageous embodiment of the present invention, RF front-end block 210 is implemented using enhancement-mode high electron mobility transistors (E-HEMT). Such transistors may be fabricated from extremely high electron mobility semiconductors (e.g., InP, ABCS III-V alloy materials, etc.)

BPF 215 receives the incoming RF signal and isolates the frequencies of interest in, for example, a 2.4 GHz pass band from unwanted out-of-band interferers. The filtered RF signal is then amplified by VGA 220 in accordance with the gain setting received from AGC block 230. Frequency discriminator 225 then converts the filtered, amplified RF signal directly to a differential output baseband signal. AGC block 230, illustrated in FIG. 2 as coming from the frequency discriminator 225, adjusts the gain of VGA 220 to maintain the RF signal amplitude into the discriminator in the desired range of signal strength.

In an advantageous embodiment, VGA 220 is a very low supply voltage amplifier that achieved significant gain per stage using by using E-HEMTs. Also, frequency discriminator is a high impedance device implemented using small channel width E-HEMTs. While CMOS may provide a practical implementation, the present disclosure incorporates a high mobility material, like indium phosphide (InP) or an antimonide-based compound semiconductor (ABCS) (both III-V semi-conductors) in to receiver 120. Typically, this material is used to make semiconductors operating at high microwave frequency (25-100 GHz). Available gains on the order of 10 to 13 dB per stage of amplification are achievable. The same device, when used at one-tenth the frequency, has significantly more gain available, on the order of 15 to 20 dB, but at much lower power consumption.

Differential input switched capacitor correlator 255 implements a programmable binary tap-weighted FIR filter that is controlled by clock signals and tap-weight inputs received from clock and logic functions block 265. The output of correlator 255 is an analog signal that is generally near zero, but peaks when the code for which correlator 255 has been programmed is detected in the received FSK signal. Address decision logic 260 detects the peak in the output of correlator 255 and implements wake-up decision logic that activates the other circuitry (e.g., more extensive communications or sensor functions and transmitter path) in the system in which receiver 120 is implemented.

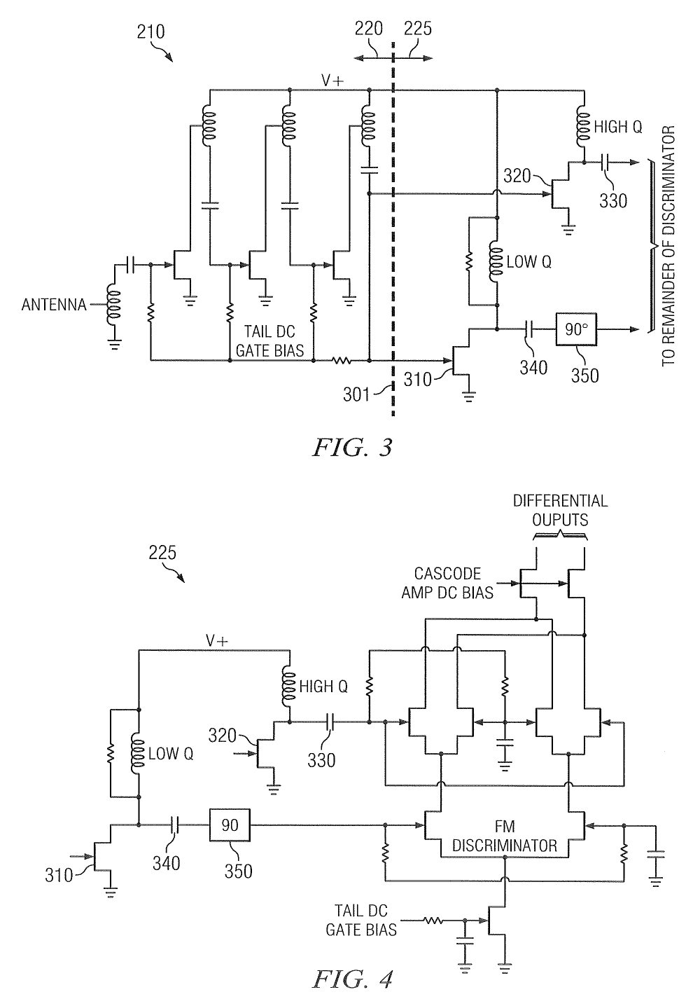

FIG. 3 illustrates in greater detail RF front-end 210 according to one embodiment of the present disclosure. Dotted line 310 demarcates the cascaded amplifier stages of VGA 220 and the input stages of discriminator 225. Each of the stages of VGA 220 implements an inductor-capacitor (LC) resonator load. A tail DC gate bias voltage received from AGC 230 is applied to the gate of the E-HEMT in each amplifier stage. While these AGC DC gate bias inputs are shown in common in FIG. 3, it may be advantageous for purposes of optimizing noise figure and signal balance to provide separate AGC inputs to some or all of these gates. The cascaded amplifier design is illustrated with dual outputs (one high-Q and one low-Q) to provide the two different inputs (with different phase versus frequency characteristics) needed into the phase-comparator or analog multiplier circuit illustrated in FIG. 4 to implement the frequency discriminator function.

The power consumption for each stage in VGA 220 is on the order of 10 μW to 50 μW. This may be achieved using L_{g}=35 nm III-V HEMTs, scaled to small channel widths (W=2 μm to 10 μm), operating from a very low supply voltage (V_{dd}=50-200 mV) with gate bias only slightly above threshold (V_{gs}−Vₜ=25 mV to 100 mV). The use of very high impedance loads in the amplifier design (preferably 25 Kohm or higher at resonance) enables gains approaching 20 dB/stage at 2.45 GHz, even under severely current-starved (i.e., transconductance-starved) operating conditions. This implementation reduces the required amount of stages needed by a factor of two over CMOS.

The last two stages in FIG. 3 (to the right of line 301) are the input stages of discriminator 225. Enhancement mode high mobility electron transistor (E-HEMT) 310 drives a low-Q load that is coupled by capacitor 340 and 90-degree phase shifter 350 to the remainder of frequency discriminator 225. E-HEMT 320 drives a high-Q load that is coupled by capacitor 330 to the remainder of frequency discriminator 225. FIG. 4 illustrates in greater detail the remaining stages of frequency discriminator 225 according to one embodiment of the present disclosure.

It is well known that the optimum FSK detector is an RF correlation detector. However, due to the complexity of an RF correlation detector, the present disclosure instead implements an FM discriminator. While there are many ways to implement a frequency discriminator, most involve low-impedance RF filters or delay lines. Driving these circuits consumes a large amount of power. The present disclosure implements an analog multiplier circuit to implement a sin(s)*cos(x) operation (or phase detector type of discriminator). The sin(x) input a high-Q (rapid change of phase with f_{sig}) signal driven by E-HEMT 320. The cos(x) input is a 90-degree shifted, low-Q (slow change of phase with f_{sig}) copy of the signal driven by E-HEMT 310. The discriminator curve is determined by the difference in phase between the two inputs. The advantage of the use of the resonant circuits as inputs is that it remains possible to operate in the very high load impedance regime, where driver power levels can be extremely low.

Within the current steering exclusive-OR (XOR) analog multiplier, the stacking of two levels of differential pairs on top of a current source and then topped off by a cascode output buffer pair means that even for a V_{ds}=100 MV to 200 mV HEMT drain-source voltage, the minimum output voltage will be 0.4 to 0.8 volts on these differential Vₒᵤₜ(f_{sig}) outputs.

Advantageously, the DC current that passes through frequency discriminator 225 may be “reused” to provide charging current for the voltage sampling capacitors in differential input switched capacitor correlator 255. In other words, the current into and out of the differential outputs of frequency discriminator 225 either charges or discharges the capacitors in correlator 255, depending on the binary value (i.e., +1 or −1) of the sample.

Since generating an additional drain supply potential would add complexity, this implies operation of the discriminator stages directly from the same V_{DD}=0.5 V to 1.8 V supply used to power the correlator, clock and other baseband logic functions. The implication of this is that, unlike an amplifier stage in which, for example, a drain current (I_{ds})=100 μa would cost only 10-20 μW (at V_{DD}=0.1−0.2 V), even a tail current (Iₜₐᵢₗ)=50 μa for this stack would cost up to 75 μW of power (at V_{DD}=1.5 V). Since even a 50 μa tail current gets divided among a number of transistors as it proceeds up the stack, it is clear that these transistors must function well at extremely low currents and, as such, are the most severely scaled in width of the E-HEMTs on the chip.

Unlike most FSK systems for which the frequency deviations are typically less than a few hundred kilohertz, communication system 100 uses large frequency shifts. By using relatively large frequency shifts (deviations) from the nominal carrier (i.e., ±5 MHz to ±10 MHz from f_{c}) and a relatively broad discriminator frequency response curve (about 30-50 MHz wide), the need for critical tuning in the RF stage can be avoided and in addition allows for some source frequency agility if required. The direct-conversion architecture potentially suffers from a DC offset problem which can be corrected in the correlator (baseband processor).

By using large deviations and DC offset suppression in the correlator, there is no need to keep discriminator 225 well-centered on the unshifted center frequency (f_{c}), so long as the shifted signals remain on the slope of the Vout (f_{sig}) discriminator response curve, as the baseband processor will be effectively AC-coupled in looking for the FSK-modulated coding. This minimizes frequency tuning requirements in RF front-end block 210, making it cost effective for implementation in integrated circuit form. While wide frequency deviations are proposed, receiver 120 may be implemented with much smaller frequency deviations (narrow band FSK), at the cost of some interference immunity, potential loss of frequency agility, and some tighter frequency stability requirements on transmitter 110.

Like most switched-capacitor circuits, voltage samples of the input signal are stored on capacitors in switched-capacitor correlator 255. However, instead of charging these signal storage capacitors using an operational amplifier, the present disclosure connects multiple copies of the sampling capacitors (one copy for each calculation for which that voltage sample will be needed) directly to the signal inputs, to be charged by the inputs, not power-consuming operational amplifiers.

Additionally, these voltage samples are not moved around (as is typical in switched-capacitor designs), but rather remain static until needed in the actual correlation calculations. The calculations are performed by passively summing separately all of the positive tap weight voltage samples and all of the negative tap weight voltage samples. Thus, the sampling capacitors double as integrating (summing) capacitors and the static power dissipation of the operational amplifier is eliminated. The differencing between the summed positive and negative tap weight voltage samples in correlator 255 may itself optionally be implemented with an operational amplifier, but its loading and duty cycle can be low, for minimal power consumption. An operational amplifier or similar comparator function may also be used in the address decision logic 260, but again the loading and duty cycle are low so that the energy consumption is minimal.

The analog output signal of correlator 255 is near-zero for continuous wave signals and is very small for random noise, signals with other than the programmed orthogonal code, and for the programmed code at times other than when it is in synchronism. But the analog output signal gives a high correlation peak when the code for which it has been programmed is detected in the FSK signal in synchronism with the correlator clock. To achieve this ideal correlator performance, the correlator and transmitter clocks must be synchronized to within a small fraction of a clock cycle (e.g., a small fraction of a microsecond for a 1 MHz clock).

Since maintaining timekeeping within the ultra-low power receiver to this accuracy, uncorrected over long periods of time, would represent an unrealistic power burden, a method of establishing this transmitter-receiver synchronism for each isolated transmission is required. In one simple method to facilitate this synchronism, transmitter 110 retransmits the FSK code multiple times with varying phase offsets to insure getting within one quarter or one eighth of a clock cycle in order to obtain at least 75% to 87.5% of maximum correlation peak amplitude.

Since RF front-end block 210 and correlator block 250 operate from different voltages, at least one power converter 270 is required to generate at least one of the voltages. In fact, it is likely that since lithium cells typically operate in the 2.8 V to 3 V range, whereas the clock, correlator and other baseband logic functions will operate with optimal energy consumption in the V_{DD}=0.5 V to 1.5 V range, at least two such power converters will typically be required.

Power conversion is always an energy (power) losing proposition. In particular, typical power converters operate by continuously measuring their output voltage with constant adjustments to either increase or decrease the output voltage to keep it as close as possible to the nominal voltage setpoint value. The constant monitoring and adjusting leads to very significant levels of static power consumption (independent of the power load on the converter). Since the total power load on a converter in this ultra-low power application may well be under 100 μW, maintaining conversion efficiency requires that this static power consumption be made extremely small.

To minimize static power, power converter 270 operates as a low-duty cycle, pulsed power conversion device. By duty cycling power converter 270, the static currents associated with power converter 270 are virtually eliminated when power converter 270 is not in actual operation to charge its output capacitor 280. The circuitry loading the power converter(s) (i.e., RF front-end block 210) is, of course always-on and hence requires a constant source of power. One approach to this problem, illustrated in FIG. 2, uses a super capacitor 280 (e.g., 0.05 F) to store charge to maintain the output voltage to the load circuitry while the power converter is turned off, permitting a duty cycled approach with relatively long off periods.

In another preferred embodiment of the power converters, a power converter circuit capable of isolated single-cycle operation that dispenses a precise amount of charge into the output capacitor each time it is cycled is utilized in a sigma-delta digital-to-analog converter-like operation to provide current pulsed to the load at just the rate necessary to match the current utilization by the circuits it drives. This allows for very infrequent measurements of the output voltage, for ultra-low static power, while at the same time allowing the capacitance value of the output capacitor 280 to be greatly reduced.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. For use in a battery-operated device, an ultra low-power receiver comprising:
a radio frequency (RF) front-end block for receiving and demodulating an incoming frequency shift-keyed (FSK) signal, the RF front-end block including:
an amplifier for amplifying the received FSK signal, the amplifier comprising a first plurality of RF transistors capable of RF gain at extremely low supply voltages and current levels; and
a frequency discriminator for demodulating the amplified FSK signal to thereby produce a baseband signal, the frequency discriminator comprising a second plurality of RF transistors capable of RF gain at extremely low supply voltages and current levels; and
a correlator for receiving the baseband signal from the frequency discriminator and detecting therein a codeword, wherein the codeword is one of an orthogonal codeword and a near-orthogonal codeword.

2. The ultra low-power receiver as set forth in claim 1, wherein the first and second pluralities of RF transistors comprises enhancement mode, high-mobility electron transistors.

3. The ultra low-power receiver as set forth in claim 1, wherein the correlator comprises a plurality of switched capacitors for storing samples of the baseband signal.

4. The ultra low-power receiver as set forth in claim 3, wherein the correlator is operable to couple the plurality of switched capacitors in order to integrate the samples stored thereon.

5. The ultra low-power receiver as set forth in claim 1, wherein the RF front-end block operates from a first DC power supply of between approximately 0.05 volts and 0.2 volts.

6. The ultra low-power receiver as set forth in claim 5, wherein the correlator operates from a second DC power supply of between approximately 0.5 volts and 1.8 volts.

7. The ultra low-power receiver as set forth in claim 1, wherein the incoming RF signal has a constant power envelope and a relatively narrow spectrum.

8. The ultra low-power receiver as set forth in claim 1, wherein the amplifier is a variable gain amplifier controlled by an automatic gain control block associated with the ultra low-power receiver.

9. The ultra low-power receiver as set forth in claim 1, further comprising a pulsed, low-duty cycle, switching power converter.

10. The ultra low-power receiver as set forth in claim 9, further comprising a relatively large capacitor that is charged by the pulsed, low-duty cycle, switching power converter and supplies power to the ultra low-power receiver when the power converter is OFF.

11. A wireless communication system comprising:
a plurality of transmitters for transmitting to a plurality of ultra low-power receivers a frequency shift keyed (FSK) downlink signal having a constant power envelope and relatively narrow spectrum; and
the plurality of ultra low-power receivers for receiving the FSK downlink signal, wherein each of the ultra low-power receivers comprises:
a radio frequency (RF) front-end block for receiving and demodulating the FSK downlink signal, the RF front-end block including:
an amplifier for amplifying the received FSK downlink signal, the amplifier comprising a first plurality of RF transistors capable of RF gain at extremely low supply voltages and current levels; and
a frequency discriminator for demodulating the amplified FSK downlink signal to thereby produce a baseband signal, the frequency discriminator comprising a second plurality of RF transistors capable of RF gain at extremely low supply voltages and current levels; and
a correlator for receiving the baseband signal from the frequency discriminator and detecting therein a codeword, wherein the codeword is one of an orthogonal codeword and a near-orthogonal codeword.

12. The wireless communication system as set forth in claim 11, wherein the first and second pluralities of RF transistors comprises enhancement mode, high-mobility electron transistors.

13. The wireless communication system as set forth in claim 11, wherein the correlator comprises a plurality of switched capacitors for storing samples of the baseband signal.

14. The wireless communication system as set forth in claim 13, wherein the correlator is operable to couple the plurality of switched capacitors in order to integrate the samples stored thereon.

15. The wireless communication system as set forth in claim 11, wherein the RF front-end block operates from a first DC power supply of between approximately 0.5 volts and 0.2 volts.

16. The wireless communication system as set forth in claim 15, wherein the correlator operates from a second DC power supply of between approximately 0.5 volts and 1.8 volts.

17. The wireless communication system as set forth in claim 11, wherein the modulated downlink signal has a constant power envelope and a relatively narrow spectrum.

18. The wireless communication system as set forth in claim 11, wherein the amplifier is a variable gain amplifier controlled by an automatic gain control block associated with the ultra low-power receiver.

19. The wireless communication system as set forth in claim 11, further comprising a pulsed, low-duty cycle, switching power converter.

20. The wireless communication system as set forth in claim 19, further comprising a relatively large capacitor that is charged by the pulsed, low-duty cycle, switching power converter and supplies power to the ultra low-power receiver when the power converter is OFF.
